(19) United States
(12) Patent Application Publication
(10) Pub. No.: US 2026/0178085 A1
(43) Pub. Date: Jun. 25, 2026

(54) DISPLAY DEVICE AND ELECTRONIC DEVICE INCLUDING THE SAME

(71) Applicant: Samsung Display Co., LTD., Yongin-si (KR)

(72) Inventors: YOUNJEONG GOH, Yongin-si (KR); KICHEOL SONG, Yongin-si (KR); YOUNGMOON KIM, Yongin-si (KR)

(21) Appl. No.: 19/369,263

(22) Filed: Oct. 26, 2025

(30) Foreign Application Priority Data
Dec. 23, 2024 (KR) 10-2024-0194155

(51) Int. Cl. G06F 1/16

(52) U.S. Cl. CPC G06F 1/1656; G06F 1/1641

(57) ABSTRACT

A display device includes a display module including a light-emitting element, and a window module including a folding region and a plurality of non-folding regions. The window module includes a window including an elastomer, a window protecting layer disposed on the window, a first adhesive layer interposed between the window and the window protecting layer, and a second adhesive layer interposed between the window and the display module. At least one of the first adhesive layer or the second adhesive layer includes acrylic-silicone-urethane-based organic particles.

This application claims priority to Korean Patent Application No. 10-2024-0194155, filed on Dec. 23, 2024, and all the benefits accruing therefrom under 35 U.S.C. § 119, the content of which in its entirety is herein incorporated by reference.

### BACKGROUND

### 1. Field

Embodiments of the disclosure described herein relate to a display device and an electronic device including the same, and more particularly, relate to a foldable display device including a window module having excellent flexibility and excellent impact resistance and an electronic device including the same.

### 2. Description of the Related Art

In general, an electronic device, such as a smart phone, a digital camera, a laptop computer, a navigation, or a smart television, which provides an image to a user, includes a display device to display the image. The display device generates an image and provides the image to a user through a display screen.

Recently, as a technology of a display device is developed, various types of display devices are being developed. For example, various types of display devices are being developed to be transformed in the form of a curve surface, foldable, or rollable.

### SUMMARY

Embodiments of the disclosure provide a foldable display device improved in folding reliability and impact resistance, and an electronic device including the same.

In an embodiment of the disclosure, a display device includes a display module including a light-emitting element, and a window module including a folding region and a plurality of non-folding regions next (adjacent) to the folding region, and disposed on the display module, The window module includes a window including an elastomer, a window protecting layer disposed on the window, a first adhesive layer interposed between the window and the window protecting layer, and a second adhesive layer interposed between the window and the display module. At least one of the first adhesive layer or the second adhesive layer includes acrylic-silicone-urethaneacrylic-silicone-urethane-based organic particles.

In an embodiment, a weight percentage of silicon in the acrylic-silicone-urethaneacrylic-silicone-urethane-based organic particles may be 10 wt % to 30 wt %.

In an embodiment, the elastomer may include polyether block amide (“PEBA”), polyurethane acrylate (“PUA”), or thermoplastic polyurethane (“TPU”).

In an embodiment, the first adhesive layer may include the acrylic-silicone-urethaneacrylic-silicone-urethane-based organic particles.

In an embodiment, the second adhesive layer may include the acrylic-silicone-urethaneacrylic-silicone-urethane-based organic particles.

In an embodiment, the first adhesive layer including the acrylic-silicone-urethaneacrylic-silicone-urethane-based organic particles or the second adhesive layer including the acrylic-silicone-urethaneacrylic-silicone-urethane-based organic particles may have storage modulus ranging from 0.160 megapascal (MPa) to 0.450 MPa at a temperature of −20 degrees Celsius (° C.).

In an embodiment, the first adhesive layer including the acrylic-silicone-urethaneacrylic-silicone-urethane-based organic particles or the second adhesive layer including the acrylic-silicone-urethaneacrylic-silicone-urethane-based organic particles may have storage modulus ranging from 0.028 MPa to 0.090 MPa at a temperature of 25° C.

In an embodiment, the first adhesive layer including the acrylic-silicone-urethaneacrylic-silicone-urethane-based organic particles or the second adhesive layer including the acrylic-silicone-urethaneacrylic-silicone-urethane-based organic particles may have storage modulus ranging from 0.014 MPa to 0.056 MPa at a temperature of 60° C.

In an embodiment, the window has storage modulus ranging from 70 MPa to 1000 MPa at a temperature of 25° C.

In an embodiment, the display device may be in-foldable and out-foldable.

In an embodiment of the disclosure, a display device includes a display module including a light-emitting element, and a window module including a folding region and a plurality of non-folding regions next (adjacent) to the folding region, and disposed on the display module, The window module may include a window including an elastomer, a window protecting layer disposed on the window, a first adhesive layer interposed between the window and the window protecting layer, and a second adhesive layer interposed between the window and the display module. At least one of the first adhesive layer or the second adhesive layer includes acrylic-silicone-urethane-based organic particles, and a weight percentage of silicon in the acrylic-silicone-urethane-based organic particles is 10 wt % to 30 wt %.

In an embodiment, the window may include an elastomer.

In an embodiment, the window may include PEBA, PUA, or TPU.

In an embodiment, the first adhesive layer may include the acrylic-silicone-urethane-based organic particles.

In an embodiment, the second adhesive layer may include the acrylic-silicone-urethane-based organic particles.

In an embodiment, the first adhesive layer including the acrylic-silicone-urethane-based organic particles or the second adhesive layer including the acrylic-silicone-urethane-based organic particles has storage modulus ranging from 0.160 MPa to 0.450 MPa at a temperature of −20° C.

In an embodiment, the first adhesive layer including the acrylic-silicone-urethane-based organic particles or the second adhesive layer including the acrylic-silicone-urethane-based organic particles may have storage modulus ranging from 0.028 MPa to 0.090 MPa at a temperature of 25° C.

In an embodiment, the first adhesive layer including the acrylic-silicone-urethane-based organic particles or the second adhesive layer including the acrylic-silicone-urethane-based organic particles have storage modulus ranging from 0.014 MPa to 0.056 MPa at a temperature of 60° C.

In an embodiment, the window may have storage modulus ranging from 70 MPa to 1,000 MPa at a temperature of 25° C.

In an embodiment of the disclosure, an electronic device including a display module including a display panel including a light-emitting element, and an impact absorbing layer disposed on the display panel, a window module disposed on the display module, a housing disposed under the display module and coupled to the window module to receive the display module. The window module includes a window including an elastomer, a window protecting layer disposed on the window, a first adhesive layer interposed between the window and the window protecting layer, and a second adhesive layer interposed between the window and the impact absorbing layer. At least one of the first adhesive layer or the second adhesive layer includes acrylic-silicone-urethane-based organic particles, and a weight percentage of silicon in the acrylic-silicone-urethane-based organic particles is 10 wt % to 30 wt %.

### BRIEF DESCRIPTION OF THE DRAWINGS

The above and other embodiments, advantages and features of the disclosure will become apparent by describing in detail embodiments thereof with reference to the accompanying drawings.

FIG. 1A is a perspective view illustrating an embodiment of an electronic device unfolded according to the disclosure.

FIG. 1B is a perspective view illustrating an embodiment of an electronic device in an in-folding procedure according to the disclosure.

FIG. 1C is a perspective view illustrating an embodiment of an electronic device in an out-folding procedure according to the disclosure.

FIG. 2A is a perspective view illustrating an embodiment of an electronic device unfolded according to the disclosure.

FIG. 2B is a perspective view illustrating an embodiment of an electronic device in an in-folding procedure according to the disclosure.

FIG. 3 is an exploded perspective view illustrating an embodiment of an electronic device according to the disclosure.

FIG. 4 is a cross-sectional view illustrating an embodiment of a display panel according to the disclosure.

FIG. 5 is a plan view illustrating an embodiment of a display module according to the disclosure.

FIG. 6 is a cross-sectional view illustrating an embodiment of a display device according to the disclosure.

FIG. 7 is a block diagram illustrating an embodiment of an electronic device according to the disclosure.

FIG. 8 is a view schematically illustrating an embodiment of an electronic device according to the disclosure.

### DETAILED DESCRIPTION

While the disclosure is susceptible to various modifications and alternative forms, illustrative embodiments thereof are illustrated in the drawings and will be described herein in detail. However, it should be understood that there is no intent to limit the disclosure to the particular forms disclosed, but on the contrary, the disclosure is to cover all modifications, equivalents, and alternatives falling within the spirit and scope of the disclosure.

In this specification, the singular forms are intended to include the plural forms unless the context clearly indicates otherwise.

In this specification, it will be further understood that the terms “comprise,” “include,” or “including,” or “have” or “having” specify the presence of stated features, numbers, steps, operations, components, parts, or the combination thereof, but do not preclude the presence or addition of one or more other features, numbers, steps, operations, components, components, and/or the combination thereof.

In the specification, the expression that a first component (or region, layer, or part) is “on”, “connected to”, or “coupled to” a second component refers to that the first component is directly on, connected to, or coupled to the second component or refers to that a third component is interposed therebetween.

In addition, the terms “under”, “at a lower portion”, “above”, “an upper portion” are used to describe the relationship between components illustrated in drawings. The terms are relative and will be described with reference to a direction indicated in the drawing.

In this specification, the wording “disposed on” may indicate the wording “disposed under any member” as well as the meaning “disposed on the member”.

In this specification, the wording “a certain member is directly disposed” may refer to that an additional layer, film, region, or plate is absent between a part, such as a layer, film, region, or plate, and another part, such as another layer, film, region, or plate. For example, the wording “a certain member is directly disposed” may refer to that the member is interposed between two layers or two members without an additional member such as an adhesive member.

In this specification, the term “and/or” includes any and all combinations of one or more of associated components.

In this specification, although the terms “first”, or “second” may be used to describe various components, the components should not be construed as being limited by the terms. The terms are only used to distinguish one component from another component. For example, without departing from the scope and spirit of the disclosure, a first component may be referred to as a second component, and similarly, the second component may be referred to as the first component. The singular forms are intended to include the plural forms unless the context clearly indicates otherwise.

Unless otherwise defined, all terms (including technical terms and scientific terms) used in the specification have the same meaning as commonly understood by one skilled in the art to which the disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

The same reference numerals will be assigned to the same components. In addition, in drawings, thicknesses, proportions, and dimensions of components may be exaggerated to describe the technical features effectively.

Hereinafter, embodiments of the disclosure will be described with reference to drawings.

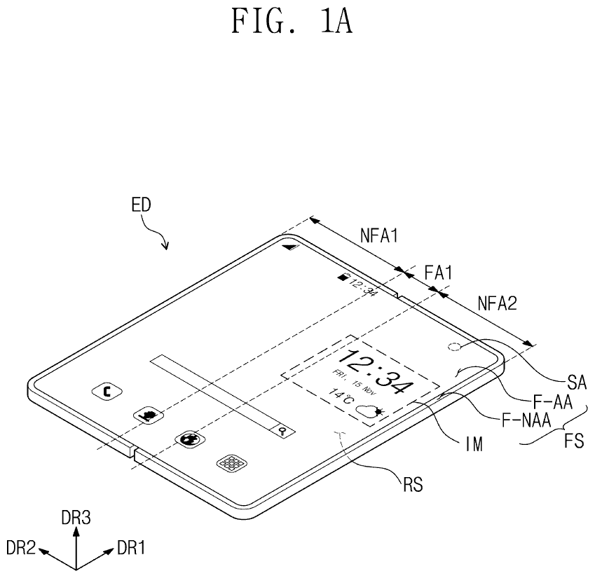

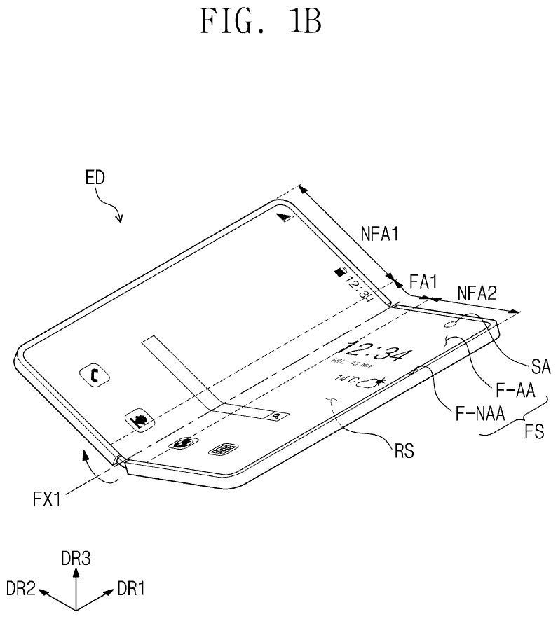

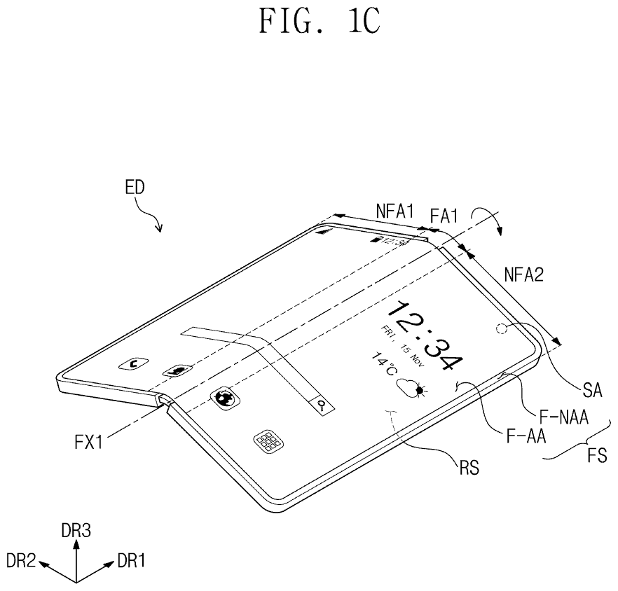

FIG. 1A is a perspective view illustrating an embodiment of an electronic device ED unfolded according to the disclosure. FIG. 1B is a perspective view illustrating the electronic device ED, which is in an in-folding procedure, illustrated in FIG. 1A. FIG. 1C is a perspective view illustrating the electronic device ED, which is in an out-folding procedure, illustrated in FIG. 1A.

The electronic device ED may be a device, which is activated, in response to an electrical signal. In an embodiment, the electronic device ED may be a cellular phone, a tablet, a vehicle navigation system, a game console, or a wearable device, for example, but the disclosure is not limited thereto. FIGS. 1A to 1C illustrate that the electronic device ED is a cellular phone.

In FIG. 1A and the following drawings, a first direction DR1, a second direction DR2, and a third direction DR3 are illustrated, and directions indicated by the first to third directions DR1, DR2, and DR3 described in this specification may be provided as the relative concept and may be changed to different directions.

Referring to FIGS. 1A to 1C, the electronic device ED in an embodiment of the disclosure may include a display surface FS that is defined by the first direction DR1 and the second direction DR2 crossing the first direction DR1. The electronic device ED may provide an image IM for a user through the display surface FS. The electronic device ED in an embodiment may display an image on the display surface FS, which is parallel to each of the first direction DR1 and the second direction DR2, such that the image IM is displayed in the third direction DR3. In this specification, a front surface (or a top surface) and a rear surface (or a bottom surface) of each component are defined based on a direction in which the image IM is displayed.

The electronic device ED in an embodiment may detect an external input applied from the outside. The external input may include various types of inputs which are provided from the outside of the electronic device ED. In an embodiment, as well as a contact by a part, such as a user hand, of a human body, the external input may include an external input (e.g., a hovering input) which is applied in a state in which the user hand approaches the electronic device ED or is next (adjacent) to the electronic device ED within a predetermined distance, for example. In addition, the external input may have various types such as force, pressure, a temperature, and a light.

The display surface FS of the electronic device ED may include an active region F-AA and a peripheral region F-NAA. The active region F-AA may be activated in response to an electrical signal. The electronic device ED in an embodiment May display the image IM through the active region F-AA. In addition, various types of external inputs may be sensed in the active region F-AA. The peripheral region F-NAA is next (adjacent) to the active region F-AA. The peripheral region F-NAA may have a predetermined color. The peripheral region F-NAA may surround the active region F-AA. Accordingly, the shape of the active region F-AA may be substantially defined by the peripheral region F-NAA. However, this is illustrated only for the illustrative purpose, and the peripheral region F-NAA may be disposed next (adjacent) only to one side of the first active region F-AA or may be omitted. The electronic device ED in an embodiment of the disclosure may include various shapes of active regions, and the disclosure is not limited to a particular embodiment.

The active region F-AA may include a sensing region SA. The sensing region SA may have various electronic modules disposed therein. In an embodiment, the electronic module may include at least one of a camera module, a speaker, a light sensing sensor, or a heat sensing sensor, for example. The sensing region SA may sense an external subject received through the display surface FS or may provide a sound signal, such as a voice, to the outside through the display surface FS. The electronic module may include a plurality of components, and the disclosure is not limited to a particular embodiment.

The sensing region SA may be surrounded by the active region F-AA and the peripheral region F-NAA. However, the disclosure is not limited thereto. The sensing region SA may be disposed in the active region F-AA, and the disclosure is not limited to a particular embodiment. FIG. 1A illustrates one sensing region SA, and the number of the sensing regions SA is not limited thereto.

The sensing region SA may be a portion of the active region F-AA. Accordingly, the electronic device ED may display an image even on the sensing region SA. When the electron modules disposed in the sensing region SA are deactivated, the sensing region SA may display a video or an image while functioning as the display surface FS.

In an embodiment, a rear surface RS of the electronic device ED may be a surface facing the display surface FS. In an embodiment, the rear surface RS, which functions as an external surface of the electronic device ED, may not display the video or the image. However, the disclosure is not limited thereto. The rear surface RS may function as a second display surface to display the video or the image. In addition, in an embodiment, the electronic device ED may further include a sensing region disposed on the rear surface RS. The sensing region disposed on the rear surface RS may include a camera, a speaker, or a light sensing sensor disposed therein.

The electronic device ED may include a folding region FA1 and non-folding regions NFA1 and NFA2. The electronic device ED may include a plurality of non-folding regions NFA1 and NFA2. In an embodiment, the electronic device ED may include the first and second folding regions NFA1 and the second non-folding region NFA2 disposed while interposing the folding region FA1 between the first and second folding regions NFA1 and NFA2. Although FIGS. 1A to 1C illustrate the electronic device ED including one folding region FA1 in an embodiment, the disclosure is not limited thereto. In an embodiment, a plurality of folding regions may be defined in the electronic device ED, for example. In an embodiment, the electronic device ED may be folded about a plurality of folding axes, such that portions of the display surface FS face each other. The number of the folding axes and the number of the non-folding regions depending on the number of the folding axes is not limited to a particular embodiment.

Referring to FIGS. 1B and 1C, the electronic device ED in an embodiment may be folded about the first folding axis FX1. The first folding axis FX1 illustrated in FIGS. 1B and 1C may be a virtual axis extending in the first direction DR1 and the first folding axis FX1 may be parallel to the direction of a longer side of the display device DD. However, the disclosure is not limited thereto. The extending direction of the first folding axis FX1 is not limited to the first direction DR1.

The first folding axis FX1 may extend in the first direction DR1 on the display surface FS, or may extend in the first direction DR1 under the rear surface RS. Referring to FIG. 1B, in an embodiment, the first non-folding region NFA1 and the second non-folding region NFA2 face each other, and the electronic device ED may be in the in-folding state such that the display surface FS is not exposed to the outside. Referring to FIG. 1C, the electronic device ED in an embodiment may be folded about the first folding axis FX1 and may be changed to be in an out-folding state in which one region of the rear surface RS, which is overlapped with the first non-folding region NFA1, and another region of the rear surface RS, which is overlapped with the second non-folding region NFA2, face each other.

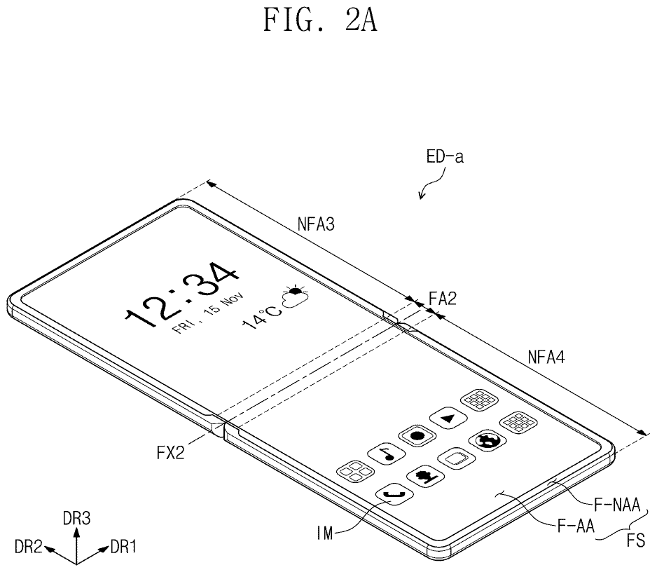

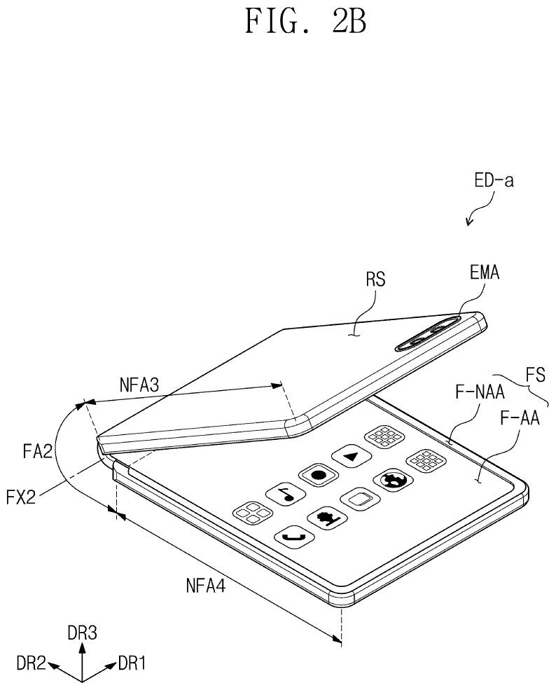

FIG. 2A is a perspective view illustrating an embodiment of an electronic device ED-a unfolded according to the disclosure. FIG. 2B is a perspective view illustrating the electronic device ED-a, which is in an in-folding state, illustrated in FIG. 2A.

In an embodiment, the electronic device ED-a may be folded about a second folding axis FX2 extending in one direction parallel to the first direction DR1. FIG. 2B illustrates that the extending direction of the second folding axis FX2 is parallel to an extending direction of a shorter side of the electronic device ED-a. However, the disclosure is not limited thereto.

In an embodiment, the electronic device ED-a may include at least one folding region FA2 and non-folding regions NFA3 and NFA4 next (adjacent) to the folding region FA2. The non-folding regions NFA3 and NFA4 may be spaced apart from each other while interposing the folding region FA2 between the non-folding regions NFA3 and NFA4.

The folding region FA2 has a predetermined curvature and the predetermined radius of curvature. In an embodiment, the first non-folding region NFA3 and the fourth non-folding region NFA4 may face each other, and the electronic device ED-a may be in the in-folding state to prevent the display surface FS from being exposed to the outside.

In an embodiment, when the electronic device ED-a is unfolded, the display surface FS may be viewed by a user, and when the etching device ED-a is in the in-folding state, the rear surface RS may be viewed by the user. In addition, although not illustrated, the electronic device ED-a in an embodiment may be in the out-folding state such that the display surface FS is exposed to the outside.

In an embodiment, the electronic device ED-a may include the second display surface RS, and the second display surface RS may be defined as a surface facing at least a portion of the first surface FS. In the in-folding state, the second display surface RS may be viewed by the user. The second display surface RS may include an electronic module region EMA in which an electron module including various components is disposed. In an embodiment, an image may be provided through the second display surface RS.

In an embodiment, the electronic device ED or ED-a may repeat the switch from the unfolding operation to an in-folding or output-folding operation and the switch from the in-folding or out-folding operation to the unfolding operation, but the disclosure is not limited thereto. According an embodiment of the, the electronic device ED or ED-a may select one of the unfolding operation, the in-folding operation, and the out-folding operation.

Although FIGS. 1A to 2B illustrate that the electronic device ED or ED-a is a foldable electronic device to be transformed to be in a folding shape, but the disclosure is not limited thereto. In an embodiment, the electronic device ED or ED-a may be a flexible electronic device to be transformed to be in a bending state or a rolling state.

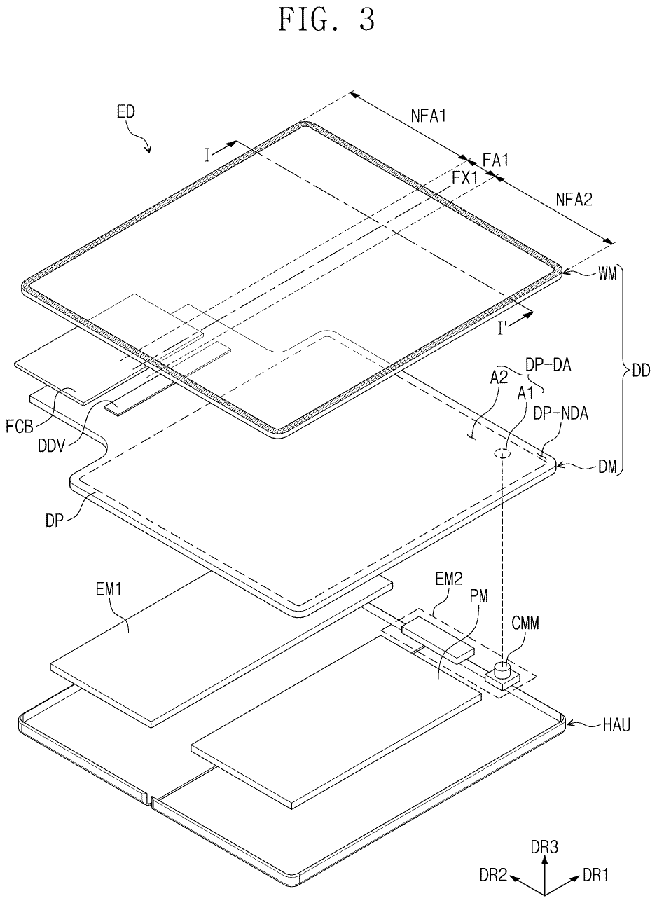

FIG. 3 is an exploded perspective view of an embodiment of the electronic device ED according to the disclosure.

Referring to FIG. 3, the electronic device ED may include a display device DD. The display device DD may include a display module DM and a window module WM disposed on the display module DM to protect the display module DM.

In an embodiment, the electronic device ED may further include a first electronic module EM1, a second electronic module EM2, a power module PM, and/or a housing HAU. The electronic device ED may further include a mechanical structure to control the folding operation.

The display module DM may at least include a display panel DP. The display module DM may generate an image. The window module WM may provide a front surface of the electronic device ED.

Although FIG. 3 illustrates that the display module DM is the same as the display panel DP, the display module DM may be in a stack structure in which a plurality of components including the display panel DP are stacked. The details of the stack structure of the display module DM will be described later.

The display panel DP may include a display region DP-DA and a non-display region DP-NDA corresponding to the active region F-AA (refer to FIG. 1A) and the peripheral region F-NAA (refer to FIG. 1A) of the electronic device ED, respectively. In this specification, “a region/part corresponding to another region/part” refers to “the region/part overlapped with the another region/part”, but does not refer to that the region/part and the another region/part have the same area.

The display region DP-DA may include a first region A1 and a second region A2. The first region A1 may be overlapped with or correspond to the sensing region SA (refer to FIG. 1A) of the electronic device ED. In an embodiment, the first region A1 is illustrated in the shape of a circle. However, the first region A1 may have a polygonal shape, an oval shape, a figure having at least one curved side, or an atypical shape, but the disclosure is not limited to a particular embodiment. The first region A1 may be also referred to as a component region, and the second region A2 may be also referred to as a main display region or a general display region.

The first region A1 may have the transmittance higher than the transmittance of the second region A2. In addition, the first region A1 may have a resolution lower than a resolution of the second region A2, but the disclosure is not limited thereto. In an embodiment, although the first region A1 has the transmittance higher than the transmittance of the second region A2, the resolution of the first region A1 may be substantially equal to the resolution of the second region A2, for example. The first region A1 may be overlapped with a camera module CMM to be described later. In an embodiment of the disclosure, a portion, which corresponds to the first region A1, of the display panel DP may be removed. Accordingly, the image may not be displayed on the first region A1.

The display module DM may at least include the display panel DP which actually generates an image. The display panel DP may be an emissive-type display panel. In an embodiment, the display panel DP may be an organic light-emitting display panel, an inorganic light-emitting display panel, an organic-inorganic light-emitting display panel, a quantum dot display panel, a micro-LED display panel, or a nano-LED display panel, for example.

The display module DM may further include a touch panel disposed on the display panel DP to sense an external input applied thereto from an outside. The external input may be a user input. The user input may include various types of external inputs such as an input made by a part of a user physical body, a light, heat, a pen, or pressure.

The display module DM may further include an anti-reflective layer disposed on the touch panel. The anti-reflective layer may be directly formed on the touch panel when the display module DM is manufactured. The anti-reflective layer may be defined in the form of a film for preventing an external light from being reflected. The anti-reflective layer may reduce the reflectance of external light which is incident above from the electronic device ED toward the display panel DP. In an embodiment, the touch panel may be formed directly on the display panel DP, and the anti-reflective layer may be formed directly on the touch panel, for example, but the disclosure is not limited thereto. In an embodiment, the touch panel may be separately manufactured and attached to the display panel DP by an adhesive layer, and the anti-reflective layer may be separately manufactured and attached to the touch panel by an adhesive layer, for example.

The display module DM may include a data driver DDV disposed on the non-display region DP-NDA. The display module DM may further include a flexible circuit film FCB coupled to the non-display region DP-NDA.

The data driver DDV may include a driving component to drive a pixel of the display panel DP. The data driver DDV may include a data driving circuit, for example. Although FIG. 3 illustrates that the data driver DDV is disposed (e.g., mounted) on the display panel DP, but the disclosure is not limited thereto. In an embodiment, the data driver DDV may be disposed (e.g., mounted) on the flexible circuit film FCB, for example.

The power module PM may supply power desired for the overall operation of the electronic device ED. The power module PM may include a conventional battery module.

A first electronic module EM1 and a second electronic module EM2 may include various functional modules to operate the electronic device ED. Each of the first electronic module EM1 and the second electronic module EM2 may be directly disposed (e.g., mounted) on a mother board electrically connected to the display panel DP or disposed (e.g., mounted) on a separate substrate to be electrically connected to a mother board through a connector.

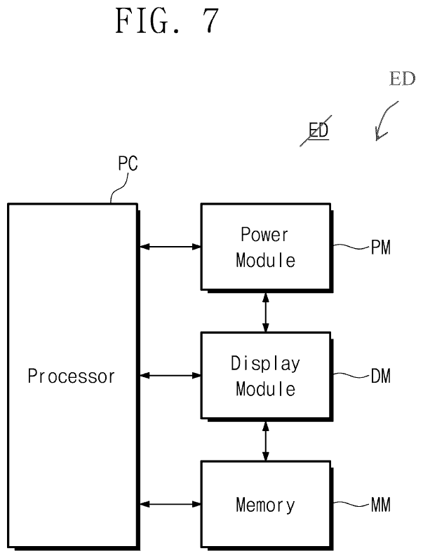

The first electronic module EM1 may include a processor PC and a memory MM. The processor PC and the memory MM will be described below with reference to FIG. 7.

The second electronic module EM2 may include the camera module CMM. The camera module CMM may capture a still image and a moving picture. A plurality of camera modules CMM may be provided. Among them, some camera modules CMM may be overlapped with the first region A1. An external input (e.g., a light) may be provided to the camera module CMM through the first region A1. In an embodiment, the camera module CMM may receive a natural light through the first region A1 to capture an external image, for example.

The housing HAU may receive the display module DM, the first and second electronic modules EM1 and EM2, and the power module PM. The housing HAU may protect components, such as the display module DM, the first and second electronic modules EM1 and EM2, and the power module PM received in the housing HAU. The housing HAU may be coupled to the window module WM.

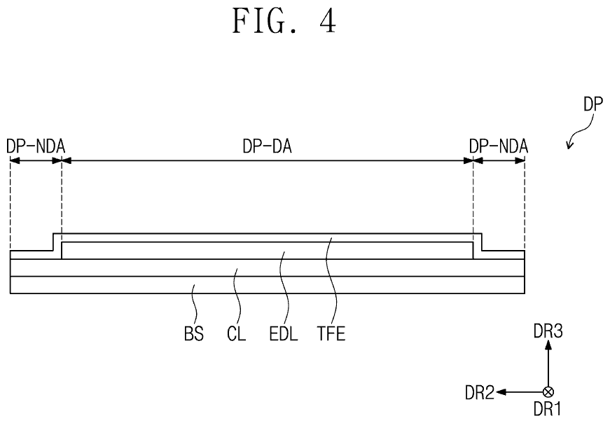

FIG. 4 is a cross-sectional view illustrating an embodiment of the display panel DP, according to the disclosure.

FIG. 4 illustrates the display panel DP of FIG. 3.

Referring to FIG. 4, the display panel DP may include the display region DP-DA and the non-display region DP-NDA around the display region DP-DA. The display panel DP may include a base layer BS, a circuit layer CL, a light-emitting element layer EDL, and an encapsulating layer TFE.

The base layer BS may provide a base surface for disposing the circuit layer CL. The base layer BS may be a flexible substrate allowing bending, folding, or rolling. The base layer BS may include a plastic substrate, a glass substrate, a metal substrate, or an organic/inorganic composite material substrate. The base layer BL may have a multi-layer structure. In an embodiment, the base layer BS may include an inorganic layer, a synthetic resin layer, or a composite material layer, for example.

The circuit layer CL may be disposed on the base layer BS. The circuit layer CL may include at least one insulating layer, a semiconductor pattern, and a conductive pattern. After forming the insulating layer, the semiconductor layer, and the conductive layer through the coating process or the deposition process, the insulating layer, a semiconductor layer, and a conductive layer are patterned through a plurality of photolithography processes, thereby forming the insulating layer, the semiconductor pattern, and the conductive pattern of the circuit layer CL. The insulating layer, the semiconductor pattern, and the conductive pattern included in the circuit layer CL may form driving elements, such as transistors, signal lines, and pads, in the circuit layer CL.

The light-emitting element layer EDL may be disposed on the circuit layer CL. The light-emitting element layer EDL may include a light-emitting element. Light-emitting elements in the light-emitting element layer EDL may be electrically connected to the driving elements in the circuit layer CL to generate light and display an image in response to a signal provided from the driving elements.

The encapsulating layer TFE may be disposed on the light-emitting element layer EDL to encapsulate the light-emitting elements. The encapsulating layer TFE may improve the optical efficiency of the light-emitting element layer EDL or may include at least one thin film to protect the light-emitting element layer EDL. The encapsulating layer TFE may protect the light-emitting element layer EDL from moisture, oxygen, and external foreign substances.

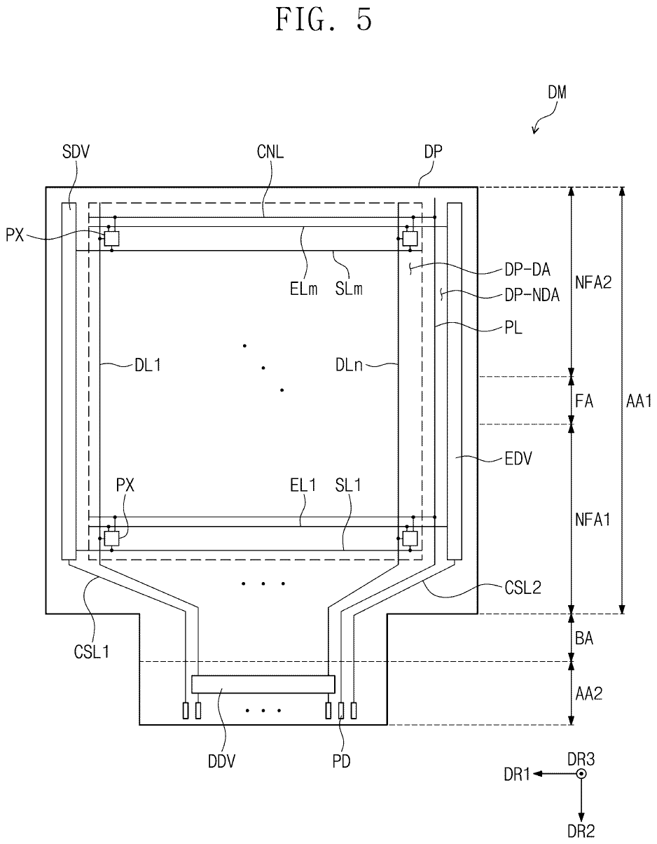

FIG. 5 is a plan view illustrating an embodiment of the display module DM according to the disclosure.

Referring to FIG. 5, the display module DM may include the display panel DP, a scan driver SDV, the data driver DDV, and an emission driver EDV.

The display panel DP may include a first region AA1, a second region AA2, and a bending region BA between the first region AA1 and the second region AA2. The bending region BA may extend in the first direction DR1, and the first region AA1, the bending region BA, and the second region AA2 may be arranged in the second direction DR2.

The first region AA1 may include the display region DP-DA and the non-display region DP-NDA around the display region DP-DA. The non-display region DP-NDA may surround the display region DP-DA. The display region DP-DA may be a region for displaying an image, and the non-display region DP-NDA may be a region in which the image is not displayed. The second region AA2 and the bending region BA may be regions in which the image is not displayed.

The first region AA1 may include a first non-folding region NFA1, a second non-folding region NFA2, and a folding region FA interposed between the first non-folding region NFA1 and the second non-folding region NFA2 when viewed in the first direction DR1.

The display panel DP may include a plurality of pixels PX, a plurality of scan lines SL1 to SLm, a plurality of data lines DL1 to DLn, a plurality of emission lines EL1 to ELm, a first control line CSL1, a second control line CSL2, a power line PL, a plurality of connecting lines CNL, and a plurality of pads PD. In this case, ‘m’ and ‘n’ are natural numbers. The pixels PX may be disposed in the display region DP-DA, and may be connected to the scan lines SL1 to SLm, the data lines DL1 to DLn, and the emission lines EL1 to ELm.

The scan driver SDV and the emission driver EDV may be disposed in the non-display region DP-NDA. The scan driver SDV and the emission driver EDV may be disposed in the non-display regions DP-NDA next (adjacent) to opposite sides of the first region AA1 in the first direction DR1. The data driver DDV may be disposed in the second region AA2. The data driver DDV may be manufactured in the form of an integrated circuit chip and may be disposed (e.g., mounted) on the second region AA2.

The scan lines SL1 to SLm may extend in the first direction DR1 and be electrically connected to the scan driver SDV. The data lines DL1 to DLn may extend in the second direction DR2 and may be connected to the data driver DDV through the bending region BA. The emission lines EL1 to ELm may extend in the first direction DR1 to be connected to the emission driver EDV.

The power line PL may extend in the second direction DR2 and may be disposed in the non-display region DP-NDA. The power line PL may be interposed between the display region DP-DA and the emission driver EDV, but the disclosure is not limited thereto. In an embodiment, the power line PL may be interposed between the display region DP-DA and the scan driver SDV, for example.

The power line PL may extend to the second region AA2 through the bending region BA. The power line PL may extend toward a lower end of the second region AA2 in a plan view. The power line PL may receive a driving voltage.

The connecting lines CNL may extend in the first direction DR1 while being arranged in the second direction DR2. The connecting lines CNL may be linked to the power line PL and the pixels PX. The driving voltage may be applied to the pixels PX through the power line PL and the connecting lines CNL connected to each other.

The first control line CSL1 may be connected to the scan driver SDV and may extend to the lower end of the second region AA2 through the bending region BA. The second control line CSL2 may be connected to the emission driver EDV and may extend to the lower end of the second region AA2 through the bending region BA. The data driver DDV may be interposed between the first control line CSL1 and the second control line CSL2.

In a plan view, the pads PD may be disposed next (adjacent) to the lower end of the second region AA2. The data driver DDV, the power line PL, the first control line CSL1, and the second control line CSL2 may be connected to the pads PD.

The data lines DL1 to DLn may be connected to relevant pads PD through the data driver DDV. In an embodiment, the data lines DL1 to DLn may be connected to the data driver DDV, and the data driver DDV may be connected to pads PD corresponding to the data lines DL1 to DLn, for example.

Although not illustrated, the printed circuit board is connected to the pads PD, and a timing controller and a voltage generator may be disposed on the printed circuit board. The timing controller may be manufactured in an integral circuit chip form and may be disposed (e.g., mounted) on the printed circuit board. The timing controller and the voltage generator may be connected to the pads PD through the printed circuit board.

The timing controller may control the operations of the scan driver SDV, the data driver DDV, and the emission driver EDV. The timing controller may generate a scan control signal, a data control signal, and an emission control signal in response to control signals received from the outside. The voltage generator may generate a driving voltage.

The scan control signal may be provided to the scan driver SDV through the first control line CSL1. The emission control signal may be provided to the emission driver EDV through the second control line CSL2. The data control signal may be provided to the data driver DDV. The timing controller may receive image signals from the outside, and convert the data format of the image signals to be matched to the interface specification with the data driver DDV, such that the converted signals are provided to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages respectively corresponding to the image data in response to the data control signal. The data voltages may be applied to the pixels PX through the data lines DL1 to DLn. The emission driver EDV may generate a plurality of emission signals in response to the emission control signal. The emission signals may be applied to the pixels PX through the emission lines EL1 to ELm.

The pixels PX may receive the data voltages in response to the scan signals. The pixels PX may display an image by emitting a light having brightness corresponding to the data voltages, in response to the emission signals. The emission time of the pixels PX may be controlled through the emission signals.

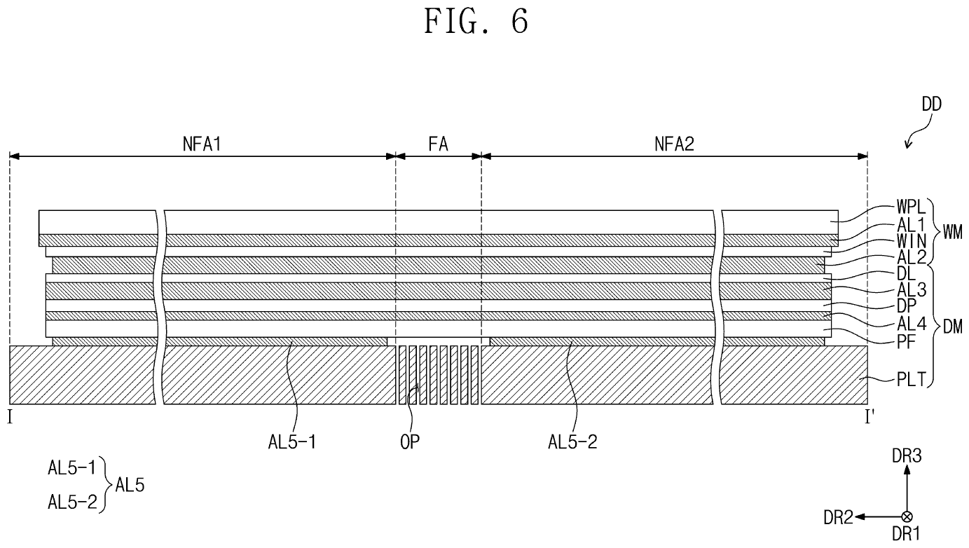

FIG. 6 is a cross-sectional view illustrating an embodiment of the display device DD according to the disclosure.

FIG. 6 is a cross-sectional view illustrating the display device DD taken along line I-I′ of the electronic device ED of FIG. 3.

Referring to FIG. 6, the display device DD may include the window module WM and the display module DM. The display device DD may include adhesive layers AL1, AL2, AL3, AL4, and AL5 disposed among several layers included in the window module WM or the display module DM. Some of the adhesive layers AL1, AL2, AL3, LA4, and AL5 may be omitted. The adhesive layers AL1, AL2, AL3, AL4, and AL5 may include a first adhesive layer AL1, a second adhesive layer AL2, a third adhesive layer AL3, a fourth adhesive layer AL4, and a fifth adhesive layer AL5.

The adhesive layers AL1, AL2, AL3, AL4, and AL5 may include any one of an optical clear adhesive (“OCA”), an optical clear resin (“OCR”), and a pressure sensitive adhesive (“PSA”).

The window module WM may be provided on the display module DM. The window module WM may transmit an image, which is provided from the display module DM, while reducing an external impact. Accordingly, the window module WM may prevent the display module DM from being broken by the external impact or from erroneously operating.

The window module WM may include a window WIN, a window protecting layer WPL disposed on the window WIN, the first adhesive layer AL1 interposed between the window WIN and the window protecting layer WPL, and the second adhesive layer AL2 disposed under the window WIN. Each of the first adhesive layer AL1 and the second adhesive layer AL2 may be also referred to as window adhesive layers.

The window WIN may be disposed on the display module DM. The window WIN may protect the display module DM from an external scratch. The window WIN may have optically transparent properties.

The window WIN may include an elastomer. In other words, the window WIN may include a material having flexibility and excellent elasticity.

In an embodiment, the window WIN may include at least one polyether block amide (“PEBA”), polyurethane acrylate (“PUA”), or thermoplastic polyurethane (“TPU”), for example. Young's modulus of the window WIN may range, e.g., from 70 MPa to 1,000 MPa. The thickness of the window WIN may range, e.g., from 50 micrometers (μm) to 200 μm.

As the window WIN includes the elastomer, the window module WM including the window WIN may have excellent flexibility and excellent impact resistance. Accordingly, according to the disclosure, the display device DD including the window module WM may have the excellent folding reliability and the excellent impact resistance. In particular, according to the disclosure, the display device DD may provide sufficiently-excellent impact resistance not only in the in-folding procedure, but also in the out-folding procedure for which impact resistance higher than that in the in-folding procedure is desired, as the display device DD is exposed to the outside. In addition, the display device DD may provide sufficiently-excellent folding reliability even in the out-folding procedure for which deformation curvature greater than that in the in-folding procedure is desired.

Table 1 shows a result obtained by evaluating an impact resistance characteristic of an embodiment of an elastomer film which is included in the window WIN according to the disclosure.

Embodiments 1 to 7 correspond to elastomer films having Young's modulus ranging from 70 MPa to 1,000 MPa. Evaluation was performed for Embodiment 1, which corresponds to a PUA film (having Young's modulus of 80 MPa) having the thickness of 100 μm, Embodiment 2, which corresponds to a PEBA film (having Young's modulus of 220 MPa) having the thickness of 100 μm, Embodiment 3 which corresponds to a PEBA film (having Young's modulus of 900 MPa) having the thickness of 100 μm, Embodiment 4, which corresponds to a PUA film (having Young's modulus of 450 MPa) having the thickness of 100 μm, Embodiment 5, which corresponds to a PUA film (having Young's modulus of 990 MPa) having the thickness of 150 μm, Embodiment 6, which corresponds to a TPU film (having Young's modulus of 80 MPa) having the thickness of 100 μm, and Embodiment 7, which corresponds to a PEBA film (having Young's modulus of 900 MPa) having the thickness of 150 μm. Comparative example 1 corresponds to a non-elastomer film, and has Young's modulus higher than that of the elastomer film. Evaluation was performed for Comparative example 1 which corresponds to a PET film (having Young's modulus of 4,370 MPa) having the thickness of 100 μm. In each of Embodiments 1 to 7, and Comparative example 1, the same acrylic PSAs (having the thickness of 75 μm) was bonded to the top surface and the bottom surface of the elastomer film (or the non-elastomer film).

In a ball drop test, an SUS ball having the diameter of 2 millimeters (mm) and the weight of 2.7 gram (g) was used. Table 1 shows the minimum height of the films according to Embodiments 1 to 7 when the films according to Embodiments 1 to 7 were broken, based on the minimum height (0) of the film according to Comparative example 1 when the film according to Comparative example 1 was broken. Table 1 shows storage modulus measured at the temperature of 25° C.

TABLE 1

| | Ball drop (cm) | Storage modulus (MPa, 25° C.) |
|---|---|---|
| Embodiment 1 | +20~ | 72 |
| Embodiment 2 | +20~ | 227 |
| Embodiment 3 | +17 | 759 |
| Embodiment 4 | +15 | 486 |
| Embodiment 5 | +7 | 1091 |
| Embodiment 6 | 0 | 36 |
| Embodiment 7 | +20~ | 812 |
| Comparative | Reference (0) | 3098 |
| example 1 | | |

Referring to Table 1, regarding the ball drop test, the films according to Embodiment 1 to 7 were broken after the ball drop at a height equal to or higher than a height for the film according to Comparative example 1. More specifically, the films according to Embodiments 1, 2, and 7 were not broken even at the height 20 centimeters (cm) higher than the height for the film according to Comparative example 1. The film according to Embodiment 3 was broken at the height 17 cm higher than the height for the film according to Comparative example 1. The film according to Embodiment 4 was broken even at the height 15 cm higher than the height for the film according to Comparative example 1. The film according to Embodiment 5 was broken at the height 7 cm higher than the height for the film according to Comparative example 1. The film according to Embodiment 6 was broken at the height equal to the height for the film according to Comparative example 1. In other words, the films according to Embodiment 1 to 7 were evaluated as elastomer films having elasticity to be applied to the foldable window module, and having impact resistance identical to or more excellent than the non-elastomer film as shown in Comparative example 1. In addition, regarding the storage modulus at a room temperature, the films according to Embodiments 1 to 7 having the storage modulus ranging from 70 MPa to 1,100 MPa were evaluated as having impact resistance sufficient to be applied to the foldable window module.

The elastomer film, which may be included in the window WIN according to the disclosure, has elasticity to exhibit excellent impact resistance even though the elastomer film has a folding characteristic. Accordingly, the window module WM including the window WIN in an embodiment of the disclosure may be applied to a foldable display device, particularly, an out-foldable display device. The display device DD including the window module WM according to the disclosure exhibits excellent folding reliability and excellent impact resistance even in an out-folding state.

The window protecting layer WPL may be disposed on the window WIN. The window protecting layer WPL may include a flexible plastic material, such as polyimide (“PI”) or polyethylene terephthalate (“PET”).

The window module WM may include a functional layer including at least one of a hard coating layer or a fingerprint preventing layer disposed on the window protecting layer WPL. In an alternative embodiment, the window module WM may include a functional layer which functions as a hard coating layer and a fingerprint preventing layer. The hard coating layer may be a layer for imparting physical strength to the window module WM. The fingerprint preventing layer may be a layer for preventing external contamination, such as a fingerprint, and suppressing abrasion due to external friction. Each of the functional layers may further include an anti-reflective function or an anti-glare function.

The first adhesive layer AL1 may be interposed between the window WIN and the window protecting layer WPL to bond the window WIN to the window protecting layer WPL. The second adhesive layer AL2 may be disposed under the window WIN to bond the window WIN and the display module DM. The thickness of the first adhesive layer AL1 and the second adhesive layer AL2 may range from 50 μm to 100 μm.

The first adhesive layer AL1 and the second adhesive layer AL2 may be Pressure Sensitive Adhesive (“PSA”). The first adhesive layer AL1 and the second adhesive layer AL2 may include organic particles. The first adhesive layer AL1 and the second adhesive layer AL2 may include on acrylic-silicone-urethane-based organic particles. However, the disclosure is not limited thereto. The first adhesive layer AL1 and the second adhesive layer AL2 may include PSA including silica nanoparticles

In an embodiment, any one of the first adhesive layer AL1 and the second adhesive layer AL2 may include acrylic-silicone-urethane-based organic particles, and a remaining one of the first adhesive layer AL1 and the second adhesive layer AL2 may not include acrylic-silicone-urethane-based organic particles. In an embodiment, the remaining one of the first adhesive layer AL1 and the second adhesive layer AL2 may include acrylic PSA which does not include acrylic-silicone-urethane-based organic particles, for example.

As the first adhesive layer AL1 and the second adhesive layer AL2 include acrylic-silicone-urethane-based organic particles, the first adhesive layer AL1 and the second adhesive layer AL2 may have flexibility and excellent impact resistance. In particular, it may be advantageous that the window WIN is applied to an out-foldable window module including elastomer instead of glass. When compared to the in-folding procedure, more excellent impact resistance is desired for the out-folding procedure due to the exposure to the outside, and is more greatly deformed in a folding part, for which the flexibility for the deformation is desired. Although the typical acrylic PSA increases polymerization and crosslinking to enhance hardness, the typical acrylic PSA is reduced in softness. Accordingly, the typical acrylic PSA is not appropriate to be applied to the out-foldable window module.

The weight ratio of silicon included in the acrylic-silicone-urethane-based organic particles may range from 10 wt % to 30 wt %. When the weight ratio is in the above range, as the acrylic-silicone-urethane-based organic particles exhibit excellent impact resistance at a relatively low temperature, a normal temperature, and a relatively high temperature, the acrylic-silicone-urethane-based organic particles may be advantageously applied to the out-foldable window module.

Table 2 shows the result of the evaluation for the impact resistance of an embodiment of the PSA including the acrylic-silicone-urethane-based organic particles, which is able to be included in the first adhesive layer AL1 and the second adhesive layer AL2 according to the disclosure.

Embodiments 8 to 14, and Comparative example 3 correspond to the PSA films including the acrylic-silicone-urethane-based organic particles, and Comparative example 2 corresponds to the acrylic PSA film without acrylic-silicone-urethane-based organic particles. The weight ratio of silicon contained in the acrylic-silicone-urethane-based organic particles is 10 wt % in the film according to Embodiment 8, 20 wt % in the film according to Embodiment 9, 25 wt % in the film according to Embodiment 10, 30 wt % in the films according to Embodiments 11 to 13, and 60 wt % in the film according to Embodiment 14. Soft urethane-based organic particles were used in Embodiments 8 to 11, and Comparative example 3, hard urethane-based organic particles were used in Embodiment 12, and the combination of the soft urethane-based organic particles and the hard urethane-based organic particles were used in Embodiment 13. The thickness of each of the films according to Embodiments 8 to 14, and Comparative examples 2 and 3 was 75 μm.

Regarding a pen drop test, a pen tip having the diameter of 0.3 mm and the weight of 3 g was used. Table 2 shows the minimum height of the films according to Embodiments 8 to 13 and Comparative example 3 when the films according to Embodiments 8 to 13 and Comparative example 3 were broken, based on the minimum height (0) of the film according to Comparative example 2 when the film according to Comparative example 2 was broken. Table 2 shows storage modulus measured at the lower temperature of −20° C., at the normal temperature of 25° C., at the higher temperature of 60° C.

TABLE 2

| | | Storage | Storage | Storage |
|---|---|---|---|---|
| | Pen | modulus | modulus | modulus |
| | drop | (MPa, | (MPa, | (MPa, |
| | (cm) | −20° C.) | 25° C.) | 60° C.) |
| Embodiment 8 | +1 | 0.160 | 0.031 | 0.018 |
| Embodiment 9 | +1 | 0.201 | 0.037 | 0.021 |
| Embodiment 10 | 0 | 0.192 | 0.029 | 0.015 |
| Embodiment 11 | +1 | 0.217 | 0.028 | 0.014 |
| Embodiment 12 | +2 | 0.440 | 0.090 | 0.056 |
| Embodiment 14 | 0 | 0.160 | 0.039 | 0.023 |
| Comparative | 0 (reference) | 0.099 | 0.033 | 0.024 |
| example 2 | | | | |
| Comparative | −1 | 0.270 | 0.020 | 0.006 |
| example 3 | | | | |

Referring to Table 2, regarding the pen drop test, the films according to Embodiments 8 to 13 were broken after the ball drop at a height equal to or higher than a height for the film according to Comparative example 2. Specifically, the film according to Embodiment 12 was broken at the height 2 cm higher than the height for the film according to Comparative example 2. The films according to Embodiments 8, 9, and 11 were broken even at the height 1 cm higher than the height for the film according to Comparative example 2. The films according to Embodiments 10 and 13 were broken at the height equal to the height for the film according to Comparative example 2. In other words, the films according to Embodiments 8 to 13 were evaluated as having impact resistance identical to or more excellent than the impact resistance of the acrylic PSA film. In the film according to Comparative example 3, the weight ratio of silicon exceeds 30 wt %. Accordingly, the film according to Comparative example 3 was broken at the height 1 cm lower than the height of the film according to Comparative example 2. The films according to Embodiments 8 to 13 had the storage modulus ranging from 0.160 MPa to 0.450 MPa at the lower temperature, the storage modulus ranging from 0.028 MPa to 0.090 MPa at the normal temperature, and the storage modulus ranging from 0.014 MPa to 0.056 MPa at the higher temperature. Accordingly, the films according to Embodiments 8 to 13 were evaluated as having the impact resistance to be applied to the foldable window module at both of the lower temperature and the higher temperature. The film according to Comparative example 2 had the lower storage modulus at the lower temperature. Accordingly, the film according to Comparative example 2 may not be applied to the foldable window module due to the lower storage modulus at the lower temperature. The film according to Comparative example 3 had the lower storage modulus at the higher temperature. Accordingly, the film according to Comparative example 3 may not be applied to the foldable window module.

The first adhesive layer AL1 and the second adhesive layer AL2 in an embodiment of the disclosure include acrylic-silicone-urethane-based organic particles containing silicon having the weight ratio ranging 10 wt % to 30 wt %. Accordingly, the first adhesive layer AL1 and the second adhesive layer AL2 in an embodiment of the disclosure exhibit excellent folding characteristics and excellent impact resistances at each of the lower temperature, the normal temperature, and the higher temperature. Accordingly, the window module WM including the first adhesive layer AL1 and the second adhesive layer AL2 in an embodiment of the disclosure may be applied to a foldable display device, particularly, an out-foldable display device. The display device DD including the window module WM according to the disclosure exhibits excellent folding reliability and excellent impact resistance even in an out-folding state.

The display module DM may include the display panel DP. The display module DM may include an impact absorbing layer DL disposed on the display panel DP. The display module DM may include a panel protecting layer PF and a support plate PLT disposed under the display panel DP.

The above description made with reference to FIGS. 1 to 5 may be identically applied to the following description about the display panel DP.

The impact absorbing layer DL may be disposed on the display panel DP. The impact absorbing layer DL may protect the display panel DP by absorbing an external impact applied from the top of the display device DD toward the display panel DP. The impact absorbing layer DL may be manufactured in the form of a stretching film. The impact absorbing layer DL may include a flexible plastic material. The flexible plastic material may be defined as a synthetic resin film. In an embodiment, the impact absorbing layer DL may include a flexible plastic material, such as PI or PET, for example. The impact absorbing layer DL may be coupled to the display panel DP through the third adhesive layer AL3.

The panel protecting layer PF may be disposed under the display panel DP. The panel protecting layer PF may be disposed under the display panel DP to protect a lower portion of the display panel DP. The panel protecting layer PF may include a flexible plastic material. In an embodiment, the panel protecting layer PF may include PET, for example. The panel protecting layer PF may be coupled to the display panel DP through the fourth adhesive layer AL4.

The support plate PLT may be disposed under the display panel DP. The support plate PLT may be disposed under the panel protecting layer PF. The support plate PLT may be coupled to the panel protecting layer PF through the fifth adhesive layer AL5. The fifth adhesive layer AL5 may include a (5-1)-th adhesive layer AL5-1 and a (5-2)-th adhesive layer AL5-2. The (5-1)-th adhesive layer AL5-1 may be disposed on the support plate PLT overlapped with the first non-folding region NFA1, and the (5-2)-th adhesive layer AL5-2 may be disposed on the support plate PLT overlapped with the second non-folding region NFA2.

The support plate PLT may be disposed under the display panel DP to support the display panel DP. The support plate PLT may include a material having a higher modulus. The support plate PLT may include a metal material or a polymer material. In an embodiment, the support plate PLT may include stainless steel, aluminum, or any alloys thereof, for example. In addition, the support plate PLT may include carbon fiber reinforced plastic (“CFRP”). However, the disclosure is not limited thereto, and the support plate PLT may include a non-metal material, plastic, glass fiber reinforced plastic, or glass. A plurality of openings OP may be defined in the support plate PLT. The plurality of openings OP may correspond to the folding region FA, in a plan view. Since the support plate PLT includes the plurality of openings OP corresponding to the folding region FA, folding may be easily made.

The display device DD may further include a lower member disposed under the support plate PLT. In an embodiment, the lower member may include at least one of a support layer, a cushion layer, or a shielding layer, for example. The configuration of the lower member may vary depending on the size, shape, or operation characteristics of the display device DD. The lower member may further include a digitizer.

The support layer may include a metal material or a polymeric material. The support layer may be disposed under the support plate PLT to support layers disposed above the support layer. In an embodiment, the support layer may be a thin metal substrate, for example.

The cushion layer may be disposed under the support layer. The cushion layer may prevent a pressing phenomenon and plastic deformation of the support plate PLT due to external impact and force. Accordingly, the cushion layer may further improve impact resistance characteristics of the display device DD. The cushion layer may include an elastomer such as a sponge, a foam, or a urethane resin. In addition, the cushion layer may include at least one of an acrylic polymer, a urethane polymer, a silicone polymer, or an imide polymer. However, the disclosure is not limited thereto.

The shielding layer may be disposed under the cushion layer. The shielding layer may be an electromagnetic wave shielding layer or a heat dissipation layer.

FIG. 7 is a block diagram of an embodiment of the electronic device ED according to the disclosure.

Referring to FIG. 7, the electronic device ED in an embodiment of the disclosure may include the display module DM, the processor PC, a memory MM, and the power module PM.

The processor PC may include at least one of a central processing unit (“CPU”), an application processor (“AP”), a graphic processing unit (“GPU”), a communication processor (“CP”), an image signal processor (“ISP”), or a controller.

The memory MM may store data information desired for the operation of the processor PC or the display module DM. When the processor PC runs the application stored in the memory MM, an image data signal and/or an input control signal may be transmitted to the display module DM, and the display module DM may process the transmitted signal and output the image information through the display screen.

The power module PM may include a power supply module, such as a power adaptor or a battery device, and a power converting module to convert the power supplied from the power supply module into power desired for the operation of the electronic device ED.

At least one of components of the above-described electronic device ED may be included in the display device DD (refer to FIG. 3) in embodiments described above. In addition, some of individual modules functionally included in one module may be included in the display device, and others of the individual modules may be provided separately from the display device DD (refer to FIG. 3). In an embodiment, the display device DD (refer to FIG. 3) may include the display module DM, and the processor PC, the memory MM, and the power module PM may be provided in the form of another device in the electronic device ED instead of the display device DD (refer to FIG. 3), for example.

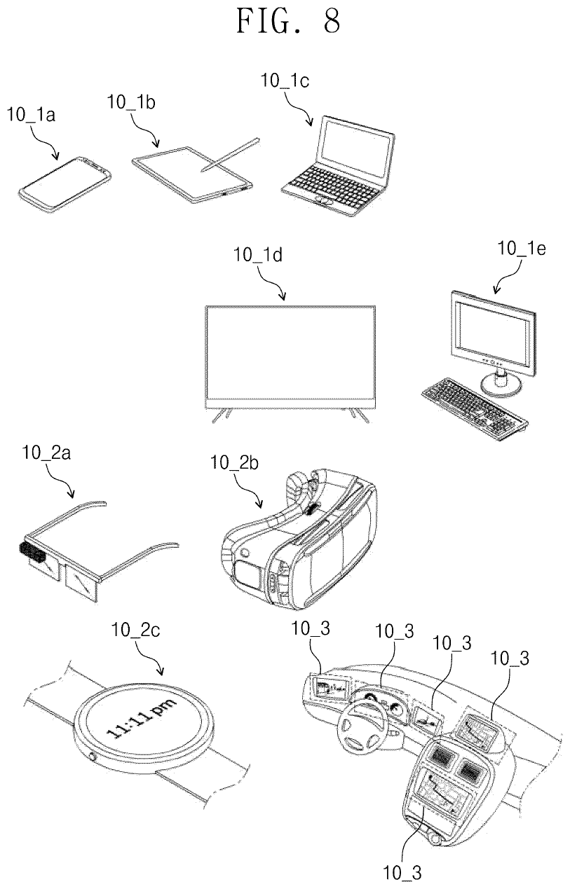

FIG. 8 is a view schematically illustrating an embodiment of the electronic module ED according to the disclosure.

Referring to FIG. 8, various electronic devices ED employing the display device DD (refer to FIG. 3) in embodiments may include a wearable electronic device including a display module such as smart glasses 10_2a, a head mounted display 10_2b, and a smart watch 10_2c, and an electronic device 10-3 for the vehicle including the display module such as a center information display (“CID”), which is disposed in an instrument panel, a centerfecia, and a dashboard of a vehicle, or a room mirror display, as well as an electronic device for image display such as a smartphone 10_1a, a tablet personal computer 10_1b, a laptop computer 10_1c, a television (“TV”) 10_1d, and a desk monitor 10_1e.

As described above, according to the disclosure, the display device and the electronic device include the window module having the excellent flexibility and the excellent impact resistance to exhibit the excellent folding reliability and the excellent impact resistance. The window module includes the window including the elastomer and the window adhesive layer including the organic particles to exhibit the excellent folding reliability and the excellent impact resistance.

Although an embodiment of the disclosure has been described for illustrative purposes, those skilled in the art will appreciate that various modifications, and substitutions are possible, without departing from the scope and spirit of the disclosure as disclosed in the accompanying claims.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. A display device comprising:
a display module including a light-emitting element; and
a window module including a folding region and a plurality of non-folding regions next to the folding region, and disposed on the display module, the window module including:
a window including an elastomer;
a window protecting layer disposed on the window;
a first adhesive layer interposed between the window and the window protecting layer; and
a second adhesive layer interposed between the window and the display module, and
at least one of the first adhesive layer or the second adhesive layer includes acrylic-silicone-urethane-based organic particles.

2. The display device of claim 1, wherein a weight percentage of silicon in the acrylic-silicone-urethane-based organic particles is 10 wt % to 30 wt %.

3. The display device of claim 1, wherein the elastomer includes polyether block amide, polyurethane acrylate, or thermoplastic polyurethane.

4. The display device of claim 1, wherein the first adhesive layer includes the acrylic-silicone-urethane-based organic particles.

5. The display device of claim 1, wherein the second adhesive layer includes the acrylic-silicone-urethane-based organic particles.

6. The display device of claim 1, wherein the first adhesive layer including the acrylic-silicone-urethane-based organic particles or the second adhesive layer including the acrylic-silicone-urethane-based organic particles has storage modulus ranging from 0.160 megapascal to 0.450 megapascal at a temperature of −20 degrees Celsius.

7. The display device of claim 1, wherein the first adhesive layer including the acrylic-silicone-urethane-based organic particles or the second adhesive layer including the acrylic-silicone-urethane-based organic particles has storage modulus ranging from 0.028 megapascal to 0.090 megapascal at a temperature of 25 degrees Celsius.

8. The display device of claim 1, wherein the first adhesive layer including the acrylic-silicone-urethane-based organic particles or the second adhesive layer including the acrylic-silicone-urethane-based organic particles has storage modulus ranging from 0.014 megapascal to 0.056 megapascal at a temperature of 60 degrees Celsius.

9. The display device of claim 1, wherein the window has storage modulus ranging from 70 megapascal to 1,000 megapascal at a temperature of 25 degrees Celsius.

10. The display device of claim 1, wherein the display device is in-foldable or out-foldable.

11. A display device comprising:
a display module including a light-emitting element; and
a window module including a folding region and a plurality of non-folding regions next to the folding region, and disposed on the display module,
wherein the window module includes:
a window;
a window protecting layer disposed on the window;
a first adhesive layer interposed between the window and the window protecting layer; and
a second adhesive layer interposed between the window and the display module,
at least one of the first adhesive layer or the second adhesive layer includes acrylic-silicone-urethane-based organic particles, and
a weight percentage of silicon in the acrylic-silicone-urethane-based organic particles is 10 wt % to 30 wt %.

12. The display device of claim 11, wherein the window includes an elastomer.

13. The display device of claim 11, wherein the window includes polyether block amide, polyurethane acrylate, or thermoplastic polyurethane.

14. The display device of claim 11, wherein the first adhesive layer includes the acrylic-silicone-urethane-based organic particles.

15. The display device of claim 11, wherein the second adhesive layer includes the acrylic-silicone-urethane-based organic particles.

16. The display device of claim 11, wherein the first adhesive layer including the acrylic-silicone-urethane-based organic particles or the second adhesive layer including the acrylic-silicone-urethane-based organic particles has storage modulus ranging from 0.160 megapascal to 0.450 megapascal at a temperature of −20 degrees Celsius.

17. The display device of claim 11, wherein the first adhesive layer including the acrylic-silicone-urethane-based organic particles or the second adhesive layer including the acrylic-silicone-urethane-based organic particles has storage modulus ranging from 0.028 megapascal to 0.090 megapascal at a temperature of 25 degrees Celsius.

18. The display device of claim 11, wherein the first adhesive layer including the acrylic-silicone-urethane-based organic particles or the second adhesive layer including the acrylic-silicone-urethane-based organic particles has storage modulus ranging from 0.014 megapascal to 0.056 megapascal at a temperature of 60 degrees Celsius.

19. The display device of claim 11, wherein the window has storage modulus ranging from 70 megapascals to 1,000 megapascals at a temperature of 25 degrees Celsius.

20. An electronic device comprising:
a display module including a display panel including a light-emitting element and an impact absorbing layer disposed on the display panel;
a window module disposed on the display module, the window module including:
a window including an elastomer;
a window protecting layer disposed on the window;
a first adhesive layer interposed between the window and the window protecting layer; and
a second adhesive layer interposed between the window and the impact absorbing layer; and
a housing disposed under the display module, and coupled to the window module to accommodate the display module,
wherein at least one of the first adhesive layer or the second adhesive layer includes acrylic-silicone-urethane-based organic particles, and
a weight percentage of silicon in the acrylic-silicone-urethane-based organic particles is 10 wt % to 30 wt %.
